(19) United States
(12) Patent Application Publication
(10) Pub. No.: US 2014/0297855 A1
(43) Pub. Date: Oct. 2, 2014

(54) Determining Rack Position of Device

(71) Applicants: David A. Moore, Tomball, TX (US); Charles W. Cochran, Spring, TX (US); Haseeb Ahsun Bhutta, Houston, TX (US)

(72) Inventors: David A. Moore, Tomball, TX (US); Charles W. Cochran, Spring, TX (US); Haseeb Ahsun Bhutta, Houston, TX (US)

(21) Appl. No.: 14/353,489

(22) PCT Filed: Dec. 17, 2011
(86) PCT No.: PCT/US11/65687

§ 371 Date: Apr. 22, 2014

(51) Int. Cl. H04L 12/24; H05K 7/14

(52) U.S. Cl. CPC H04L 41/12; H05K 7/1498
USPC 709/224

(57) ABSTRACT

A device has a chassis to mount at a respective rack position of a multi-position rack. The device has data handling components fixed to the chassis. The data-handling components include a reader to read a rack-position identity of the rack position from the rack when the chassis is mounted in the rack at the rack position. The data-handling components store device-identity data. The data-handling components are configured to transmit over a network an association relating the rack-position identity to the device-identity data.

### BACKGROUND

Racks and other types of multi-position supports can be used to store modular computer devices, e.g., hardware servers and switches. A data center may include many racks, each with many devices. Knowing the rack position of each device can facilitate efforts to trouble-shoot, repair, upgrade, and replace data-center devices.

Smart racks help keep track of device locations by identifying devices as they are inserted into a rack, e.g., by reading data from tags mounted on the devices or reading data from device communications ports. The data collected by a smart rack can then be transmitted to a database associating hardware with data-center rack locations.

### BRIEF DESCRIPTION OF THE DRAWINGS

The following figures represent examples and not the invention itself.

FIG. 1 is a schematic diagram of a data system in accordance with an example.

FIG. 2 is a flow chart of a rack-management process in accordance with an example,

FIG. 3 is a schematic diagram of data system in accordance with another example.

FIG. 4 is a flow chart of another rack management process in accordance with an example.

FIG. 5 is a schematic diagram of a PCA assembly in accordance with an example.

### DETAILED DESCRIPTION

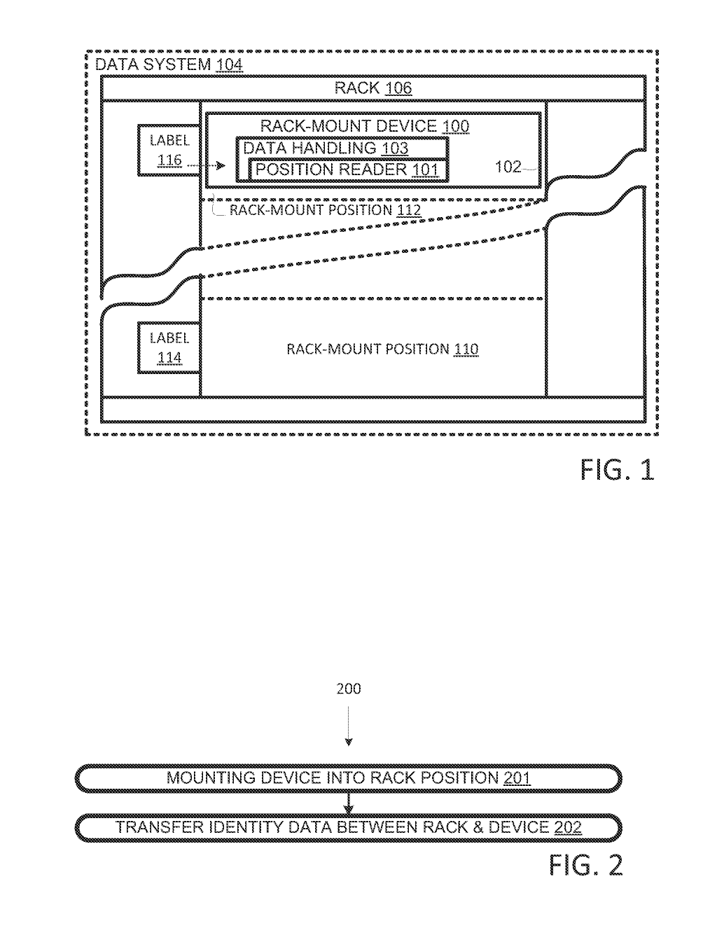

A rack-mount device 100, shown FIG. 1, includes a reader 101 for reading a “rack-position” identity of a rack position at which device 100 is mounted. For example, as shown in FIG. 1, a data system 104 includes a multi-position rack 106 with rack positions, e.g., rack positions 110 and 112. Rack 106 includes labels 114 and 116 that store, respectively, identities for rack positions 110 and 112. Rack-mount device 100 includes a chassis 102 and data-handling components 103 affixed to chassis 102 and including position reader 101. When rack-mount device 100 is mounted into rack position 112, for example, reader 101 reads an identity of rack position 112 from label 116.

Data-centers are making increasing use of virtualization technologies to provide greater management flexibility at a cost of greater management complexity. For example, if an application is suffering from performance issues, it may be desirable to troubleshoot the hardware on which the application is running. However, the application layer might only be able to identity virtual resources used by the application. A virtualization layer might then be able to identify the hardware supporting the virtual resources. Then, it is still necessary to locate the hardware, which may be in any position of any rack in any of several data centers. Data system 104 provides the data to automatically (i.e., based on machine-based data and without human input) and reliably locate a device.

Thus, data system 104 provides for data-center inventory tracking that is more immediate and efficient and less prone to error than tracking based on more manual approaches. An alternative approach to inventory tracking involving smart racks that read the identities of mounted devices introduces additional nodes to manage and, thus, complexity to a data center. Also, having a device read from a rack rather than or in addition to a rack reading from a device, makes it easier to merge rack-position data with a detailed specification for the device.

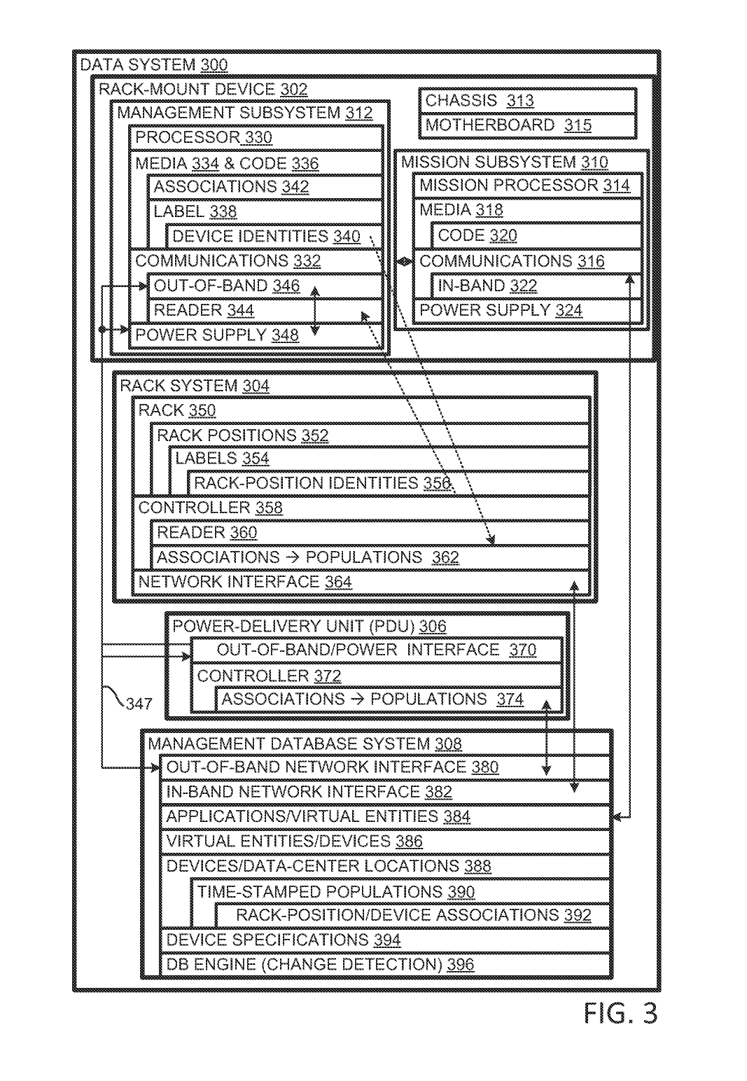

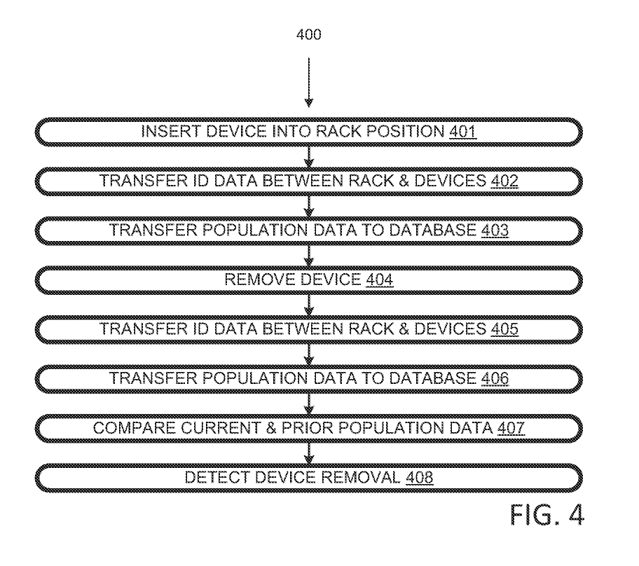

A process 200 implementable in data-system 104 is flowcharted in FIG. 2. At 201, a rack-mount device is mounted into a rack position of a multi-position rack. At 202, identity data is transferred between the rack and the mounted device. When applied to device 100 (FIG. 1), this transfer involves transferring rack-position identity data to a device mounted at the respective rack position. When applied to a device with a “separate” management processor, this transfer may involve the management processor, directly or indirectly, transferring device identity information to a rack system, as explained below with respect to FIG. 3.

As shown in FIG. 3, a data system 300 includes rack-mount devices such as rack-mount device 302, rack systems including a rack system 304, power-deliver units including a power-delivery unit 306, and a management database system 308. Herein, a “device” is a spatially delimited hardware or hardware/software hybrid system that is configured to or that may be programmed and/or arranged to perform a mission. For example, devices in a database system have missions involving processing, communicating, and storing database queries and data.

Especially in large complex data systems, devices may be managed. Management activities can include monitoring, configuring, powering on and off, etc. Many devices include management facilities and agents that assist in their management. Rack-mount device 302 includes a mission subsystem 310, a separate management subsystem 312, a chassis 313, and a motherboard 315 fixed to chassis 313. When in use, mission subsystem 310 performs mission activities, and may perform some management activities. When in use, management subsystem 312 performs management activities (of device 302) but not mission activities (of device 302).

Mission subsystem 310 includes a processor 314, communication devices 316, and storage media 318. Non-transitory storage media 318 is and may be further encoded with code 320, e.g., firmware, applications, agents, operating systems, virtual servers and other virtual devices and machines, and mission and other data. Exactly what code is involved depends on the nature of the device, its context within a host system, and its mission. Communication devices 316 may include a network interface 322 for an in-band (in that it handles mission data) network, e.g., an Ethernet network. In addition, mission subsystem 310 may include a power supply 324 and other non-data-handling components, e.g., fans.

Management subsystem 312 includes a management processor 330, communications devices 332, and storage media 334. Storage media 334 is and may be further encoded with code 336 representing, for example, management instructions and data, including monitoring and configuration data. Storage media 334 includes an electronic “label” 338 on which processor 330 may encode device identities 340, e.g., chassis and motherboard serial numbers. In addition, code 336 may represent associations 342 between device identities and identities of rack positions in which devices are mounted. Non-mission management processor 330 manipulates management data in accordance with management instructions, but does not execute mission instructions or manipulate mission data. Mission and management components are fixed to motherboard 315.

Communication devices 332 include a reader 344 for reading a rack-position from a rack in which device 302 is mounted. In addition, communication devices 332 includes an interface 346 for a network that is “out-of-band” in that, while it is used to communicate management data, it is not used to communicate mission (defined with respect to the mission of device 302) data. More specifically, out-of-band network interface 346 provides an interface to a channel 347 between management subsystem 312 and PDU 306. Channel 347 is also used to deliver power from PDU 306 to a power supply 348, which supplies power to the rest of management subsystem 312. In particular, in channel 347, management data is superimposed on the voltage power level.

Rack system 304 includes a rack (i.e., support structure) 350. Rack 350 defines rack positions 352 at which rack-mounted devices may be mounted. Labels 354 store rack-position identities 356 for respective rack positions 352. Rack system 304 includes a controller 358, which includes a reader 360 for reading device labels, e.g., label 324, when the devices are mounted in rack system 304. Controller 358 converts associations between rack positions and devices into rack populations 362 (data sets including associations between rack positions and devices) which include the associations and also indicate which rack positions are unpopulated. Rack system 304 includes a network interface 364, e.g., an Ethernet network interface, for communication with database system 308.

Power-delivery unit PDU 306 includes an out-of-band and power interface 370 and a controller 372. Interface 370 is used to communicate with device 302 and database system 308. Controller 372 converts associations received from device 302 to populations 374, which are transmitted to database system 308. Populations 374 characterize rack positions of rack system 304 that have management subsystems powered by PDU 306. Depending on the scenario, this may include all or just some of rack positions 352.

Database system 308 includes an out-of-band network interface 380 for communicating with power-delivery units including PDU 306. Database system 308 includes an in-band network interface 382 for communicating with rack systems including rack system 302 and devices and their mission subsystems such as device 302 and mission subsystem 310.

Some data centers use virtualization technologies to achieve greater management flexibility. Virtualization involves creating software abstractions of hardware. Due in part to the extensive use of virtualization, it can be difficult to determine which hardware a particular software entity is using. Database system 308 addresses this challenge by providing a database 384 that relates applications to virtual entities (e.g., virtual servers, logical disk drives, logical communication channels), a database 386 that relates virtual entities to devices, a database 388 that relates devices to data-center locations, including rack and rack position for each device. Database 388 can include time-stamped rack populations 390, which can include associations 392 between devices and rack positions. A device database 394 provides detailed specification for each device. Such specification can include makes, model numbers, and serial numbers for a device and its components, including chassis, motherboard, processors, hard disks and other storage media, and communications components.

Database system 308 can include a database engine 396 that manages databases 384, 386, 388, and 394 and can detect changes in associations 392 by comparing (e.g., successive) rack populations. This can be particularly useful for detecting when a device is removed from a rack. To this end, rack populations can be gathered to frequently, e.g., every second to ensure rapid reliable detection of a device removal (even if the device is quickly remounted).

Management database system 308 can obtain information regarding device 302 both from mission subsystem 310 and management subsystem 312. Mission subsystem 310 can provide information regarding installed applications, operating systems, virtual machines or other virtual entities, e.g., to populate databases 384 and 386. Management subsystem 312 is a source for detailed information regarding a device, its configuration, and its components. From this point of view, rack position is just one of many specifications or configuration parameters for a device.

Data from management subsystem 312 can arrive at management database system 308 via rack system 304 or PDU 306. The later route involves a minor extension to an existing out-of-band management path used for managing devices. As such, it is well suited for providing detailed information and for responding to queries, e.g., including queries regarding location and rack position. Also, data gathered and forwarded by PDUs can be used to make sure critical workloads are using devices with sufficiently redundant power supplies. On the other hand, data obtained via rack system 304 may be better form for visualizing a data center as a physical plant. Such visualization is useful for many purposes, controlling thermal distributions in a data center either by moving devices or migrating workloads. Any redundancy in the data received over different paths can be used for confirmation purposes.

In a use case, a process 400 begins with inserting a device into a rack position at 401. At 402, rack-position and/or device identification data is transferred between rack and device to form associations of rack position identifiers and device identifiers. For example, in a device-master example, rack-position identifiers can be transferred from rack to device. Alternatively, in a rack-master example, device identification and characterization data can be transferred from device to rack.

At 403, rack population data can be transferred to a management database. In a rack-master example, a rack system can assemble rack-position and device associations into a rack population data structure, which can be transferred to the database. In a device-master example, the transfer of population data may be from power-delivery units; alternatively devices may transfer associations individually, with the recognition of the population transfer being determined by examining association data in the database.

At 404, the device is removed from the rack, e.g., for maintenance, component upgrade, repair, or replacement. At 405, in an iteration of 402, identification data is transferred between rack and devices. At 406, in an iteration of 403, rack population data is transferred to the management database. At 407 the current and immediately prior rack populations are compared. At 408, the comparison of 407 is used to detect removal of a device.

A management information database can cross-link rack population data with other data, such as cloud, network, or application topology data for visualization, analytics, optimization, discovery, monitoring, and control purposes. For example, data can be combined for enhanced visualization of a data center, more detailed asset tracking, improved schemes for allocating workloads and resources, ensuring redundant systems are actually redundant (rather than, for example, being connected to the same power source), achieving favorable distributions of thermal loads, etc.

A fully populated database of physical equipment locations, cross linked to network and virtual application or cloud topology information data bases, allows differentiating service offerings. There is value in visualization and asset tracking applications, including variations that map distribution of virtualized processes or flag units with pending disk drive issues. In addition, there are applications that check for correct implementation of risk reduction strategies like power topology rules to ensure redundant power feeds, and allocation of workloads to cooler parts of the data center.

To these ends, data transferred from rack to device or from device to rack may include other information relevant to managing a data center or a collection of data centers. For example, information provided by the rack can identify the rack, e.g., by serial number, and its location in a data center, and the data center and its geographic location. In addition, the rack data can specify the size of the rack (e.g., number of “U” positions), and information regarding devices installed other than via the front of the rack. Device data transferred to a rack may specify its hardware and software components and configuration.

In some rack-master examples, each device may have a tag storing a chassis identification record (CIR) with information such as a chassis serial number, a motherboard serial number (e.g., for server devices), a media access control (MAC) address, a number of positions occupied by the device, etc. A rack can be a standard or modified RETMA (Radio Electronics Television Manufacturers Association) or EIA (Energy information Administration) rack with vertically arranged “U” positions. Device size can be expressed as a number of “U” positions.

Data specifying more than rack-position identity and device-identity may be transferred. For example, in addition to rack-position identity data, a rack may provide data identifying the rack, its size (e.g., number of rack positions), location data of the rack in a data center, and location and identity of the data center. In addition to device identity data, component identity data, device and component specifications, network identifications (e.g., MAC or “media access control” address), and connectivity may be specified.

Some examples use a single-conductor channel, e.g., using a “1-wire” technology available from Maxim Integrated Products Corporation for storing and transferring device and position identity information. This technology uses a single wire to transfer power to a device and data from the device; a second “wire” may be used for ground. Accordingly, communication may he made by two-pairs of electrically conductive contacts that engage when and once a device is fully inserted into a rack. Some contacts may be in the form of leaf springs that are compressed as a device is inserted to ensure good electrical contact.

Scene examples modify typical 1-wire practices to optimize read time, reduce parts count and provide extensive protection against bus shorts or faults. For instance, a “keep alive” watchdog timer may be used to close a bus switch that connects a Vcc supply to the reader board. This timer uses a periodic “edge” trigger to keep the bus connected. If the bus contacts are shorted by accident, the 1-wire bus could be rendered unusable. However, when the “watchdog” timer expires, the power to the reader board is disconnected. Since the switches connecting the 1-wire bus to the reader contacts power up in an open state, the short is removed from the bus when power is restored. By detecting which “U” location causes the short, the affected “U” may be flagged in a “do not use” table, and an alert sent to the central data collector noting the problem. Once this is accomplished, the rest of the rack may be read normally.

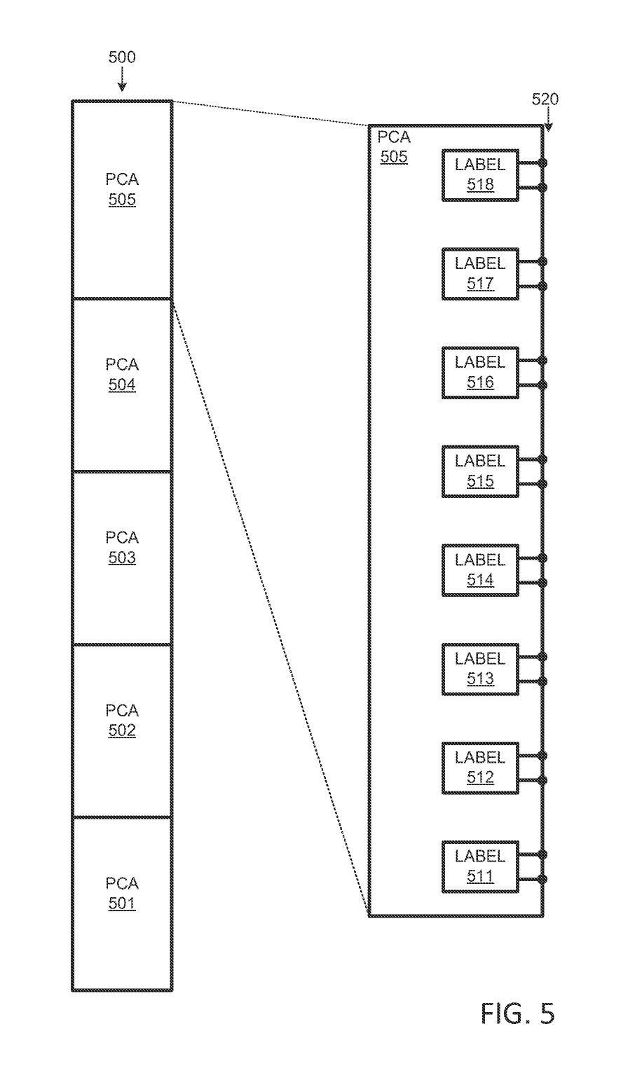

Some examples use an innovative modular construction that optimizes printed-circuit assembly (PCA) panel size and accommodates multiple rack sizes with the minimum number of component SKUs. For example, a 36U label strip is shown in FIG. 5 including four 7U PCAs 501-504 and an 8U PCA 505. By using different numbers of 7U and 8U PCAs, a variety of standard rack sizes can be accommodated.

Each PCA can include a label for each U position. For example, PCA 505 includes eight labels 511-518. A reader strip is built up of a small master board and a series of PCAs, each of which handles 7U or 8U. Each label communicates with a pair of contacts 520, one for ground and one for power and data using one-wire technology. When a device is inserted into a rack position, it can read rack position information from a respective label via these contacts.

Each label includes a hard-coded serial number, which serves as an address. A programming device can write to the labels over a common bus. A switch is used so that only one label is read at a time, so the programmer knows the serial number for each label. The labels can then be written to in parallel by addressing each label by its serial number. Alternatively, the labels can be written to serially without an addressing scheme.

All PCAs to be assembled into a label strip can be programmed in parallel so the rack position for each label for each PCA is known at the time of programming. The programming can be performed either alter the label strip is assembled or before the label strip is assembled. The information written to a label (for subsequent reading by a device) can include rack position, rack size, rack identity, rack location, and data center identity.

Herein, a “system” is a set of interacting non-transitory tangible elements, wherein the elements can be, by way of example and not of limitation, mechanical components, electrical elements, atoms, physical encodings of instructions, and process segments. Herein, “process” refers to a sequence of actions resulting in or involving a physical transformation. “Storage medium” and “storage media” refer to a system including non-transitory tangible material in or on which information is or can be encoded. “Computer-readable” characterizes storage media in which information is encoded in computer-readable form.

In this specification, related art is discussed for expository purposes. Related art labeled “prior art”, if any, is admitted prior art. Related art not labeled “prior art” is not admitted prior art. The illustrated and other described embodiments, as well as modifications thereto and variations thereupon are within the scope of the following claims.

What is claimed is:

1. A device comprising:
a chassis to mount at a respective rack position or a multi-position rack; and
data handling components fixed to said chassis, said data-handling components including a reader to read a rack-position identity of said rack position from said rack when said chassis is mounted in said rack at said rack position, said data-handling components storing device-identity data, said data-handling components being configured to transmit over a network an association relating said rack-position identity to said device-identity data.

2. A device as recited in claim 1 further comprising a motherboard hosting a non-mission management processor, said device-identity data independently identifying said chassis and said motherboard.

3. A device as recited in claim 1 further including a power delivery channel to deliver electrical power from a power delivery unit and to deliver said association to said power delivery unit.

4. A device as recited in claim 1 wherein said association specifies hardware components hosted by said device.

5. A device as recited in claim 1 wherein said association specifies a media-access control (MAC) address for said device.

6. A process comprising:
mounting a rack-mount device in a multi-position rack at a rack position of said multi-position rack;
transferring identity data between said device and said rack, said transferring including at least one element of a set consisting of
transferring rack-position data identifying said rack position from said rack to said device, and
transferring said device-identity data from a non-mission management processor of said device to said rack.

7. A process as recited in claim 6 further comprising:
forming an association between said rack-position data and said device-identity data; and
transmitting said association over a network.

8. A process as recited in claim 6 further comprising:
said rack forming rack population data sets by collecting plural associations between devices engaging respective rack positions and the respective rack positions at which the device are engaged; and
said rack transmitting said rack population data sets to a database system.

9. A process as recited in claim 8 further comprising detecting when said device is removed from said rack by comparing said rack population data sets.

10. A process as recited in claim 6 wherein said transmitting involves said device transmitting said association to a power-delivery unit over a channel used to provide power to said device.

11. A process as recited in claim 10 further comprising:
forming, by said power-delivery unit rack, population data sets by collecting plural associations between devices engaging respective rack positions and the respective rack positions at which the device are engaged; and
transmitting, by said power-delivery unit, said rack population data sets to a database system.

12. A process as recited in claim 11 further comprising detecting when said device is removed from said rack by comparing said rack population data sets.

13. A process as recited in claim 6 further comprising:
mounting a label strip including a series of printed-circuit assemblies with labels storing rack-position data; and
prior to said mounting, programming said PCAs in parallel with said rack-position data.

14. A server comprising:
a chassis to mount in a rack position of a rack;
a mission processor fixed to said chassis; and
a motherboard fixed to said chassis and hosting a non-mission management processor to handle transfers of identity data between said server and said rack, said identity consisting of at least one element selected from a set consisting of server identity data identifying said server and rack-position identity data identifying a rack-position of said rack.

15. A server as recited in claim 15 further comprising a label to store said server identity data written to said label by said non-mission management processor.

16. A server as recited in claim 13 further comprising a power-delivery channel to:
deliver from a power delivery unit electrical power consumed by said management processor; and
deliver from said management processor to said power deliver unit an association specifying said server identity data and said rack-position identity data.
